(19) United States
(12) Patent Application Publication
(10) Pub. No.: US 2008/0121176 A1
(43) Pub. Date: May 29, 2008

(54) INSTALLATION FOR DEPOSITING, BY MEANS OF A MICROWAVE PLASMA, AN INTERNAL BARRIER COATING ON THERMOPLASTIC CONTAINERS

(75) Inventor: Yves Alban Duclos, Octeville-Sur-Mer (FR)

Correspondence Address: SUGHRUE MION, PLLC, 2100 PENNSYLVANIA AVENUE, N.W., SUITE 800, WASHINGTON, DC, 20037, US

(73) Assignee: SIDEL PARTICIPATIONS, OCTEVILLE-SUR-MER (FR)

(21) Appl. No.: 11/869,930

(22) Filed: Oct. 10, 2007

(30) Foreign Application Priority Data
Oct. 13, 2006 (FR) 06 09020

(51) Int. Cl. C23C 16/511

(52) U.S. Cl. 118/712; 118/723 MW

(57) ABSTRACT

An installation for depositing, by means of a microwave plasma, a barrier coating on thermoplastic containers, comprising treatment stations (1), each of which has a chamber (2) and a cover (3) including a vacuum pumping chamber communicating with functional components grouped together in a detachable unit (7) that can be attached to the cover and that are sheltered in respective housings provided in a coupling face (8) of the detachable unit. The cover incorporates functional connections (16) necessary for the functional components and emerging on a coupling face (9) of the cover, these coupling faces being mutually matched in a complementary manner; and these connections and these housings are connected respectively when said detachable unit is mounted on the cover with their respective coupling faces mutually cooperating.

### FIELD OF THE INVENTION

The present invention relates in a general manner to the field of the production of thermoplastic containers, particularly made of PET, of which the wall is provided with an internal layer of a barrier coating, for example of carbon, silica or another material, capable of preventing or retarding molecular or ionic exchanges through the wall.

The invention more specifically relates to improvements provided to installations for depositing, by means of a microwave plasma, a coating forming a barrier on the internal face of containers made of thermoplastics such as PET, this installation comprising a multiplicity of stations for the individual treatment of containers, each of which has a treatment chamber and an upper unit forming a cover including a vacuum pumping chamber with which the functional components of said installation are in communication, liable to be covered, at least partly, with a powdery material constituting said coating during the functioning of the installation.

### BACKGROUND OF THE INVENTION

The operational procedure and an example of the structure of a treatment station for an installation of the type considered are described and illustrated in particular in document FR 2 776 540 in the name of the Applicant.

During treatment of the container, a microwave field is emitted inside the treatment chamber and this field develops towards the pumping chamber through a jacket. The microwaves that are propagated inside the jacket and inside the pumping chamber bring about deposits of particles of barrier material there (carbon, silica or another material), which contaminate the internal walls of the jacket and the pumping chamber, or even beyond that the internal walls of the pumping circuit on account of the entrainment of non-attached particles.

The result is contamination of some functional components of the installation that are at least partly covered with the powdery barrier material. This can occur for example for pressure sensors useful for controlling the vacuum levels in the chamber and in the container, sensors of which the operation is disturbed, or even which are made ineffective when their sensitive surface is made opaque by a deposit of powdery material.

However, the major disadvantage of this entrainment of powdery material lies in the fact that a portion is deposited on some particularly sensitive elements such as seals fitted to some components, in particular seals of fluid control solenoid valves (selective controls for establishing a vacuum and for re-establishing atmospheric pressure in the chamber and in the container to be treated) that are associated with the operation of the treatment station and are situated downstream from the filtration means of the vacuum pumping chamber. Deposition of powdery material on these seals reduces the elasticity thereof and reduces their capacity to deform on crushing and results in a reduction of the quality of leaktightness provided by these seals with, as a direct consequence, a reduction in the vacuum level capable of being developed in the chamber and therefore in a deterioration in the conditions for developing the plasma, leading to deposition on the container of a coating of barrier material of poorer quality. It consists here of a fundamental defect in the functioning of the installation and, in order to remedy this, it proves necessary to clean the seals regularly and also to replace them more often than would normally be necessary.

Now, in current installations, solenoid valves are mounted individually in various locations, according to the available room.

On account of this, maintenance to be provided on seals of solenoid valves calls for all the solenoid valves of the installation to be demounted and then remounted regularly, typically at the rate of 3 solenoid valves per treatment station, (namely one solenoid valve for putting the interior volume of the container under vacuum, one solenoid valve for putting the volume of the chamber outside the container under vacuum and one solenoid valve for re-establishing atmospheric pressure that is common to the internal volume of the container and to the volume of the chamber outside the container). In current machines equipped with approximately 20 treatment stations, this represents approximately 60 solenoid valves. Considerable work is involved that requires qualified labour employed over long periods and which of course means that the installation has to be immobilised for all the duration of this maintenance operation. It consists of a constraint that operators accept with increasing difficulty as the tendency today is always to search for an increase in production rates, which implies first of all a restriction of immobilization of installations to a minimum, in particular for maintenance.

Moreover, the search for even greater production rates results in an increase in the number of stations within each installation by reason in particular of the impossibility of reducing the duration of the process for depositing the barrier material layer below a certain threshold. Thus, for example, the Applicant currently envisages the production of greater capacity installations comprising a number of treatment stations increased to approximately 48, which represents 192 seals to be regularly maintained only for solenoid valves. Immobilization of the installation for very long periods required for maintenance of seals according to current practices can no longer be envisaged.

### SUMMARY OF THE INVENTION

The object of the invention is to provide a solution aimed at satisfying, at least to a large extent, practical requirements and, without seeking to deal with the problem of deposits and entrainments of powdery products when the installations are operating, to provide an improved structural arrangement for said installations that makes it possible to simplify and accelerate the process of restoring installations and to reduce considerably the time installations are immobilized.

To these ends, the invention provides, in an installation such as described in the preamble, the following arrangements:

said functional components comprise solenoid valves for selectively controlling the establishment of a vacuum and atmospheric pressure inside the chamber and inside the container to be treated and are grouped together in a detachable unit that can be attached to said cover and that are sheltered inside respective housings provided in a coupling face of said detachable unit;
the cover incorporates functional connections necessary for the respective functioning of said functional components that open on a coupling face of said cover, said coupling faces of the detachable unit and of the cover being mutually matched in a complementary manner; and
said connections and said housings sheltering the respective functional components are connected respectively when said detachable unit is mounted on said cover with their respective coupling faces mutually cooperating.

Due to the construction according to the invention, all sensitive functional components are grouped together in the detachable unit which, by virtue of simple rapid-acting means of attachment, is easily and rapidly interchangeable. It is then sufficient to replace a detachable unit that is deficient or one that is preventively considered as such, with a detachable unit in good condition so that the installation is once again operational and can be set in motion. Cleaning of one or more contaminated components of the removed unit is then carried out at a distance, and moreover in a workshop provided for this purpose with improved performance. In the case of an installation grouping together a multiplicity of treatment stations, it is sufficient to hold a complete set of detachable units in reserve so as to be able to carry out renovation of all treatment stations. The time that the installation is immobilized for this overall maintenance operation is considerably reduced in comparison with the time required for restoring an installation of a previous design.

The arrangements of the invention are particularly simple to put into practice in the case where

the treatment stations are in even numbers,
each group of treatment stations comprises two adjacent stations, and
said functional components of said two adjacent stations of a group of stations are grouped together in said common detachable unit that can be attached to the coupling faces of the covers of two respective stations.

The invention provides, in an installation such as described in the preamble, the following arrangements: the treatment stations are in even numbers, each group of treatment stations comprises two adjacent stations;

said functional components of said two adjacent stations of a group of stations are grouped together in a common detachable unit that can be attached to the coupling faces of the covers of the two respective stations and are sheltered in respective housings provided in a coupling face of said detachable unit;
said cover incorporates functional connections that are necessary for the respective functioning of said functional components and that emerge on a coupling face of said cover, said coupling faces of the detachable unit and of the cover being mutually matched in a complementary manner, and
said connections and said housings sheltering the respective functional components are connected respectively when said detachable unit is mounted on said cover with their respective coupling faces mutually cooperating.

These arrangements of the invention find an application that is particularly valuable in the case where the abovementioned functional components are solenoid valves for selectively controlling the establishment of a vacuum and the re-establishment of atmospheric pressure in the chamber and in the container to be treated, since the performance of the installation and the quality of the deposit of the barrier coat layer are all particularly dependent on the vacuum level maintained in the container and in the chamber for the formation of the plasma, this vacuum level being itself dependent to the first degree on the quality of the leaktightness provided by the seals of the solenoid valves controlling the operational cycle. However, it should be understood that other functional components such as vacuum sensors or flow meters can also be incorporated in the detachable unit.

In a concrete example of an embodiment, it is possible to provide for the housings of the solenoid valves controlling the vacuum inside the container to be positioned in portions of the detachable unit projecting on the coupling face and for the coupling face of the cover to have recesses, with complementary shapes, able to receive said projecting portions, such a layout making it possible to simplify the positioning of inlets and outlets associated with said solenoid valves. It is also possible to provide for said coupling face of the detachable unit to be projecting with respect to an assembling face supporting mechanical means of connection with the cover and for the cover to have a recess capable of receiving said projecting coupling face, which facilitates the guiding of the detachable unit when it is mounted on the respective cover and facilitates the installation of a seal between the cooperating faces of the detachable unit and of the cover.

The arrangements according to the invention can find a very valuable application in the context of a particular construction of the installation that consists of distributing the treatment stations in groups comprising several adjacent stations, of having a common detachable unit grouping together the functional components of said several adjacent stations of a group of stations, and of having said detachable unit capable of being attached to said coupling faces of said upper units of the respective stations. In this context, it is particularly advantageous for the chambers of adjacent treatment stations of a group of stations to be brought together and juxtaposed and the respective covers to be also juxtaposed. Such an arrangement leads to less room being taken up in the setting up of treatment stations and an increased number of treatment stations can be put in place in a given space. It then becomes possible to simplify still further the structure by providing for the treatment stations of a group of stations to be provided with a common single cover and said detachable unit to be attached to the coupling face of the common cover. Such an arrangement makes it possible to increase considerably the time for dismantling and remounting the covers on account of the fact that several treatment stations are treated simultaneously in a single manipulation and in this way the time for which the installation is immobilized is thus reduced in a very considerable manner.

In installations produced by the Applicant, the following are functionally associated with each work station:
a solenoid valve for controlling the establishment of a vacuum in the internal volume of the chamber outside the container to be treated,
a solenoid valve for controlling the establishment of a vacuum in the internal volume of the container to be treated,
a solenoid valve for controlling the re-establishment of atmospheric pressure inside the volume of the chamber outside the container to be treated, and
a solenoid valve for controlling the re-establishment of atmospheric pressure in the internal volume of the container to be treated.

The implementation of arrangements according to the invention that have just been described enables the installation to be structured in such a way that it can comprise a solenoid valve for controlling the establishment of a vacuum in the internal volume of the container to be treated and a solenoid valve for controlling the re-establishment of atmospheric pressure in the internal volume of the container to be treated for each treatment station and that it comprises a single solenoid valve for controlling the establishment of a vacuum in the internal volume of the chamber outside the container to be treated and a single solenoid valve for controlling the re-establishment of atmospheric pressure in the internal volume of the chamber outside the container to be treated that are common to all the treatment stations of a group of treatment stations. The result is an appreciable structural simplification of the treatment stations and a not inconsiderable saving of equipment.

The arrangements according to the invention can find an application in installations with various designs. They can in particular find an advantageous application in installations in which, for each treatment station, the cover is fixed to and integral with the respective chamber and the bottom of the chamber can be displaced axially in order to allow for the introduction and removal of containers, positioned with their necks uppermost, through the bottom of the chamber.

The arrangements according to the invention are all particularly appropriate for high performance installations with a high throughput, equipped with a large number of treatment stations, such as those of the revolving carousel type and comprising a revolving frame supporting said multiplicity of treatment stations distributed around the perimeter, in which the detachable units are mounted respectively on the sides of the covers of the treatment stations that are turned radially outwards. In this way, easy access is provided to the detachable units from outside the installation.

### BRIEF DESCRIPTION OF THE DRAWINGS

The invention will be better understood on reading the following detailed description of some preferred embodiments, given solely by way of purely illustrative examples. In this description, reference is made to the appended drawings in which:

FIG. 1 is a perspective view of part of a treatment station provided with a detachable unit according to the invention;

FIG. 2 is schematic sectional view, on an enlarged scale, showing a construction of a solenoid valve in the detachable unit of FIG. 1;

FIG. 3 is schematic sectional view on an enlarged scale showing a variant of the solenoid valve construction in the detachable unit of FIG. 1;

FIG. 4 is a partly exploded perspective view of a portion of an installation for treating containers, structured, according to a preferred embodiment of the invention, with treatment stations being grouped two-by-two;

FIG. 5 is a partly exploded perspective view, similar to that of FIG. 4, with the detachable unit detached from two treatment stations; and

FIG. 6 is a perspective view of the detachable unit with its coupling face visible.

### DETAILED DESCRIPTION OF THE INVENTION

The object of the invention is an improvement to installations structured for depositing, by means of a microwave plasma, a coating forming a barrier on the internal face of containers made of thermoplastic such as PET, such an installation comprising a multiplicity of stations for treating containers.

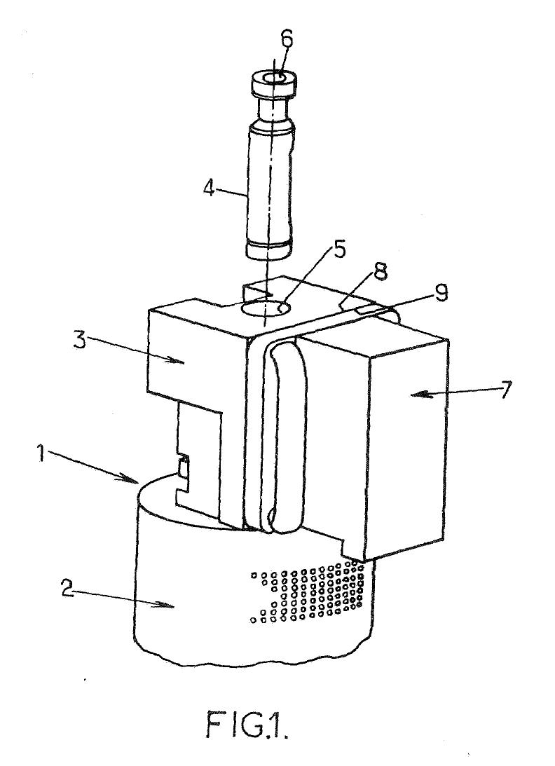

In FIG. 1, a single treatment station is shown being denoted in its entirety by the numerical reference 1, and only one part, useful for understanding the improvements provided by the invention, is shown schematically in an external perspective view.

Essentially, each treatment station 1 comprises in particular:
a treatment chamber 2 suitable for receiving at least one container to be treated and equipped so that the process can be developed there for depositing, particularly on its internal face, a coating of a barrier material (for example carbon) by means of a microwave plasma from a precursor gas injected into the chamber, and
a cover 3 surmounting the chamber 2 and including a vacuum pumping chamber (not visible in FIG. 1) in which leakproof means of connection with the container comprise a jacket 4 with a generally tubular shape coaxial with the neck of the container, and which, in order to make it easier to understand, is shown in FIG. 1 as having left its housing 5 of the cover 3. The cover 3 also supports a tubular injector (not shown) coaxially passing through (passage 6) said jacket 4 and capable of injecting a reactive fluid into the container as the process proceeds for treating said container in order to form a layer of barrier material on the internal face thereof.

A more detailed description of a treatment station arranged in this way can be found in document FR 2 872 148 in the name of the Applicant.

Functional components of said installation (not visible in FIG. 1) are in communication with this vacuum pumping chamber, these being liable to be at least partially covered, as the installation operates, with the powdery material of which said coating consists.

According to the invention, provision is made:

for the functional components (not visible in FIG. 1) to be grouped together in a detachable unit 7 that can be attached to the cover 3, preferably with the aid of rapid means of attachment and are sheltered inside respective housings provided in a coupling face 8 of said detachable unit 7;
for the cover 3 to incorporate functional connections necessary for the respective functioning of said functional components and that emerge on a coupling face 9 of said cover 3, said coupling faces 8, 9 respectively of the detachable unit 7 and of the cover 3 being mutually matched in a complementary manner; and for said connections and said housings sheltering the respective functional components to be connected respectively when said detachable unit 7 is mounted on said cover 3 with said respective coupling faces 8, 9 mutually cooperating.

In FIG. 1, the detachable unit 7 is shown mounted on the cover 3.

The functional components aimed at by the configurations proposed in the context of the invention are components of which the functioning is liable to be disturbed or even destroyed by the presence of the powdery barrier material. Pressure sensors and flow meters are particularly concerned that are put into operation in order to control the functioning of the treatment station, but also especially solenoid valves serving to control the establishment of a vacuum in the chamber from an external vacuum pump and for putting the chamber in contact with the atmosphere, solenoid valves in which the presence of powdery material on the seals of clack valves negatively affects the quality of the leak-tightness of the seal of said clack valves.

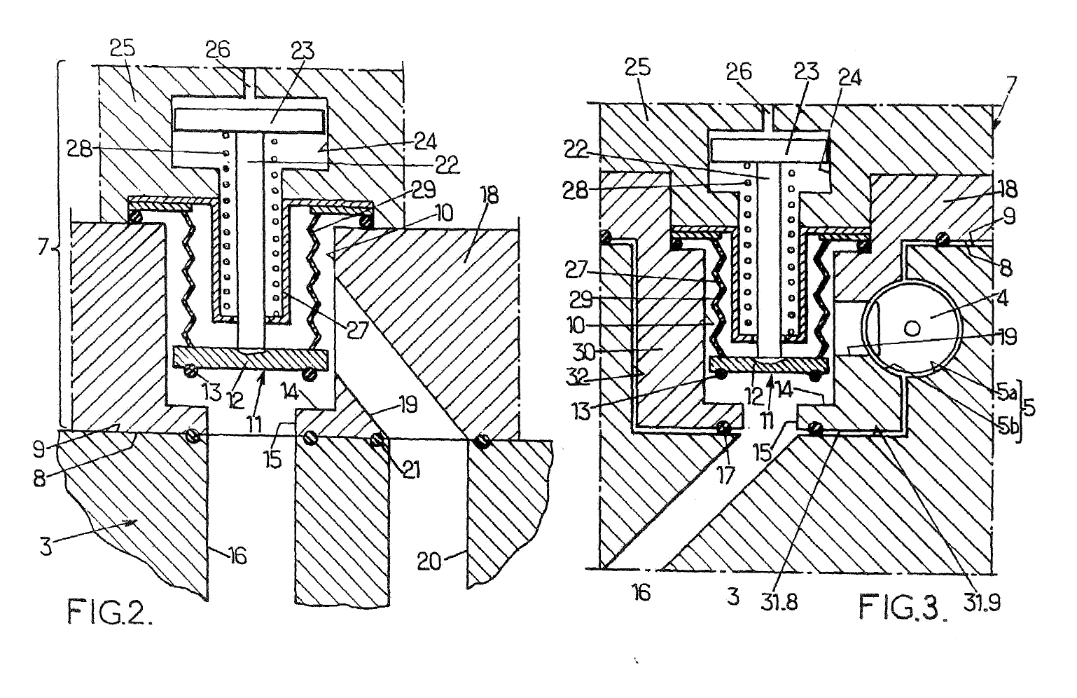

It is more precisely in relation to functional components consisting of solenoid valves that two concrete examples will now be described for configuring a detachable unit 7, with respect to the two FIGS. 2 and 3 respectively.

With reference first of all to the example of FIG. 2, the detachable unit 7 comprises a body 18 in which a housing is provided, denoted in its entirety by the numerical reference 10, that shelters all the components of a solenoid valve denoted by the numerical reference 11.

The solenoid valve 11 comprises a clack valve 12 provided with at least one seal 13 and capable of cooperating with a facing shoulder 14 surrounding an orifice 15 emerging on the front face of the body 18 constituting said coupling face 8 of the detachable unit 7. This coupling face 8 of the detachable unit 7 is shaped so as to cooperate with the opposite coupling face 9 of the cover 3 on which a passage 16 produced through the cover 3 emerges, substantially aligned coaxially with the orifice 15 of the detachable unit 7. A seal 17 is provided between the two cooperating faces 8, 9 and it can in particular be mounted on the cooperating face of the detachable unit 7, around the orifice 15.

In the housing 10, for example on the lateral wall thereof, there emerges a duct 19 drilled in the body 18 of the detachable unit 7 and which, at its opposite end, emerges on the coupling face 8 of the detachable unit 7 facing a passage 20 made in the cover 3 and emerging on the coupling face 9 thereof, a seal 21, for example supported by the detachable unit 7, being interposed between the two coupling faces 8, 9.

The valve 12 of the solenoid valve can be driven by a pneumatic cylinder. To this end, the clack valve 12 is secured, via a rod 22 to a head 23 of a movable piston in the chamber 24 produced in a body 25 of the solenoid valve attached to the body 18 of the detachable unit 7. A duct 26 for introducing pneumatic control fluid (pressurized air, typically under 7×10⁵ Pa) opens in the chamber 24 in order to control the movement of the head 23 of the piston and therefore of the valve 12. A guide sleeve 27 that extends in the housing 10, on the one hand serves to guide the rod 22 and on the other hand serves as a support at one end of a return spring 28 coaxially surrounding the rod 22 and of which the other end rests under the head 23 of the piston in order to return the movable system formed of the valve 12, the rod 22 and the piston head 23 into a rest position (corresponding in the example illustrated to the open position of the valve 12). Finally, a sealing device such as a bellows 29 is interposed in a sealed manner between the valve 12 and the body 25 of the solenoid valve.

With the aim of simplifying maintenance and to enable the solenoid valve to be replaced rapidly when needed, the solenoid valve 11 can advantageously be of the cartridge type that can be inserted in a housing of the body 18 of the detachable unit 7 (not shown in a detailed manner).

In the arrangement that has just been described in relation to FIG. 2, the coupling faces 8 and 9 belonging respectively to the detachable unit 7 and to the cover 3 are substantially flat, at least in their respective zones directly concerned by the insertion of this solenoid valve.

Another example of an arrangement is illustrated in FIG. 3, in which the same components are present. On the other hand, in a different manner from that which has been described above, the valve 12 of the solenoid valve is sheltered in a portion 30 projecting with respect to the coupling face 8 and for its part, the cover 3 has a recess 32 capable of receiving said projecting portion 30 of the detachable unit 7. It is then the seal 17 that is interposed between the front face 31.8 of the projecting portion 30 and the bottom 31.9 of the recess 32. Such a construction, which remains functionally equivalent to the preceding one, offers however the advantage of simplifying the installation in some cases, in particular for the communication intended for the establishment of a vacuum inside the container to be treated. This communication is established through the jacket 4 installed in its housing 5 provided inside the cover 3. The construction proposed within the context of this layout makes it possible to move the housing 10 sheltering the clack valve of the solenoid valve to be approximately facing the housing 5 of the jacket 4. In this way, the aforementioned duct 19 can emerge directly in this housing 5. In the example of a valuable embodiment shown in FIG. 3, the housing 5 is partly defined (5a) only in the cover 3 and partly (5b) in the projecting portion 30 and the duct 19 emerges directly in said portion 5b. In this configuration, the passage 16 is connected to the vacuum source, while the duct 19 is connected, via the jacket 4, to the internal volume of the container to be treated.

In this way, for each treatment station, the detachable unit 7 has a solenoid valve for establishing a vacuum in the internal volume of the container to be treated that is installed according to the construction illustrated in FIG. 3 and three other solenoid valves (establishment of a vacuum in the chamber outside the container, re-establishment of atmospheric pressure in the internal volume of the container, re-establishment of atmospheric pressure in the chamber outside the container) that are installed according to the construction illustrated in FIG. 2.

By virtue of the arrangement provided according to the invention when at least one seal of the solenoid valve seal has to be cleaned or replaced, the detachable unit 7 concerned is removed and replaced immediately by a detachable unit 7 in a good functional state held in reserve, which makes it possible to immobilize the installation for a very brief period. Maintenance of the removed unit is then carried out outside the machine in a workshop under optimum conditions and the renovated unit is then held in reserve.

Similarly, within the context of systematic preventative maintenance, all the detachable units 7 of the installation can be demounted and replaced by previously renovated units held in reserve and the time that the installation is immobilized is then reduced to a minimum, with on the other hand the need to have two complete sets of detachable units available.

As has already been emphasized above, the arrangements according to the invention are even more valuable when the installation is provided with a great number of treatment stations. In this context, a further improvement can be envisaged in the reduction in the time during which the installation is immobilized for the purpose of maintenance, by providing for the treatment stations 1 to be distributed in groups comprising several adjacent stations, for a common detachable unit 7 to group together the functional components of said several adjacent stations 1 of a group of stations, and for said common detachable unit 7 to be able to be attached to the coupling faces 9 of the covers 3 of respective stations.

In particular then, the chambers 2 of the adjacent treatment stations 1 of a group of stations are brought together and juxtaposed and the respective covers 3 are also juxtaposed. In this case, integration of the treatment stations 1 of the same group of stations can be progressed still further by providing for the respective covers of the treatment stations 1 of a group of stations to be joined together in the form of a common single cover 3.

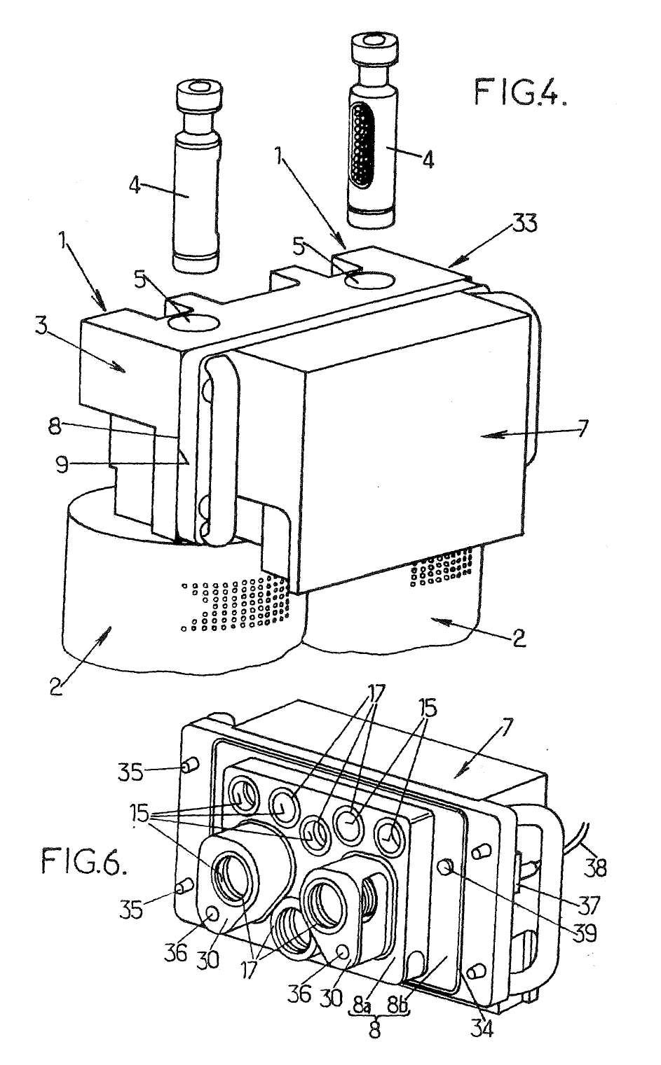

FIGS. 4 to 6 of the appended drawings illustrate the aforementioned layout in the case of an installation equipped with treatment stations that are in an even number. The treatment stations 1 are then arranged in groups of two denoted by the numerical reference 33, each group 33 of treatment stations comprising two adjacent treatment stations 1.

As will be clearly seen in FIG. 4, that is a perspective view similar to that of FIG. 1 showing a single station, the two chambers 2 are adhered together and are surmounted by a common cover 3 that groups together the respective equipment necessary for the functioning of two treatment stations. Similarly, in FIG. 1, the two jackets 4 are shown leaving their respective housings 5. The common detachable unit 7 groups together the functional components of two adjacent treatment stations of the group of stations 33 and said common detachable unit 7 can be attached, preferably by a rapid means of attachment, on the coupling face 9 of the common cover 3.

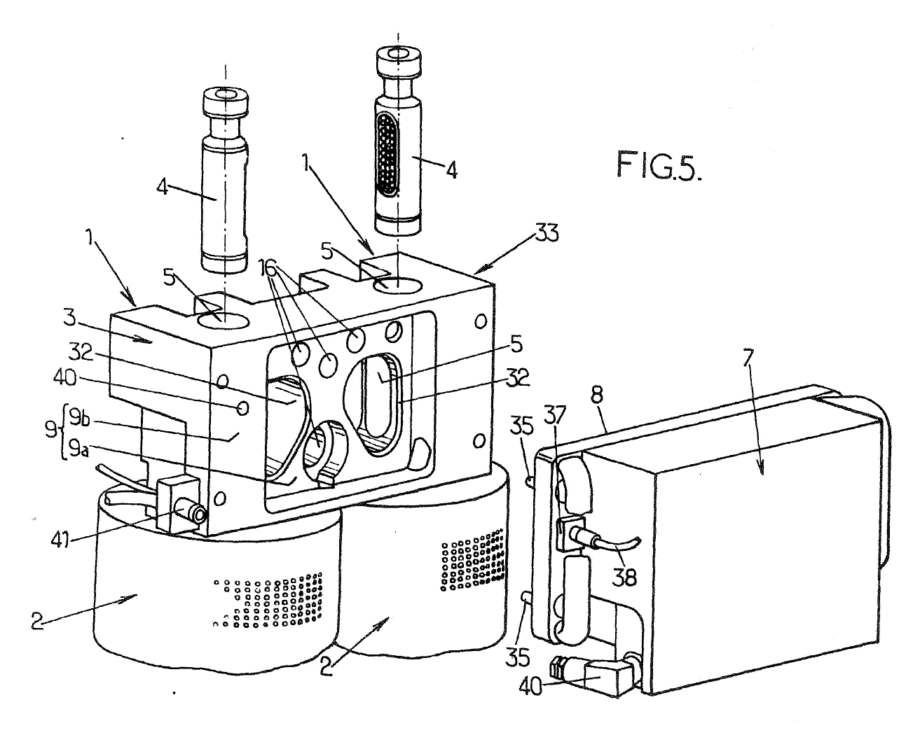

FIG. 5 represents the group 33 of treatment stations of FIG. 4 in which the detachable unit 7 is demounted and separated from the cover 3, while in FIG. 6 the detachable unit 7 is shown, in perspective, in a position turned with its coupling face 8 visible.

These two FIGS. 5 and 6 make it possible in particular to identify two solenoid valve arrangements for establishing a vacuum in the internal volumes of two containers treated by the two treatment stations 1, with in particular the projecting portions 30 of the detachable unit 30 and the recesses 32 with complementary shapes of the cover 3, partly allowing the housing 5 of a jacket 4 to appear (that situated on the right).

In FIG. 6, the seals 17 clearly appear providing individual sealing of each orifice. It will be noted that overall complementary leakproofness is procured by a seal 34 surrounding all the orifices appearing on the coupling face 8 of the common unit 7.

On account of the grouping together of solenoid valves in a common detachable unit 7, it is possible to envisage that some of these can provide a common function for the two treatment stations. With this in mind, one solenoid valve is kept for controlling the establishment of vacuum in the internal volume of the container to be treated and one solenoid valve for controlling the re-establishment of atmospheric pressure in the internal volume of the container to be treated for each treatment station, whereas a single solenoid valve can be provided for controlling the establishment of vacuum in the internal volume of the chamber outside the container to be treated and a single solenoid valve for controlling the re-establishment of atmospheric pressure in the internal volume of the chamber outside the container to be treated that are common to all the treatment stations. By virtue of this reduction in the number of solenoid valves, the cost of equipment used is reduced as well as the cost of the maintenance of the equipment that is retained and simultaneously, the volume of the common detachable unit 7 is substantially reduced, which makes it possible to reduce the overall size and weight of the installation leading to a lower inertia thereof.

In a concrete example of an embodiment, it is of value that the coupling face 8 of the detachable unit 7 is made in a staged manner so as to facilitate the guiding of the detachable unit 7 when it is mounted on the respective cover 3 and to facilitate the insertion of a seal between the cooperating faces of the detachable unit and of the cover. To this end, it is provided that the portion 8a of the coupling face that groups together the orifices 15 of the solenoid valve housings projects with respect to an assembling face 8b supporting the means 35 (visible in FIG. 6) of mechanical connection with the cover 3. In a complementary manner, such as with the use of pins, the coupling face 9 of the cover 3 has a recess 9a that is capable of receiving said portion 8a projecting from the coupling face 8 and which is surrounded by an assembling face 9b capable of cooperating with the assembling face 8b of the detachable unit 7. The aforementioned seal 34 is then put in place on the assembling face 8b as shown in FIG. 6.

Two housings are also shown in FIG. 6 sheltering the vacuum sensors 36 that emerge on the front faces of the two aforementioned respective projecting portions 30 sheltering the solenoid valves for establishing a vacuum intended respectively for two treatment stations.

Similarly, a flow meter 37 is shown in FIGS. 5 and 6 that is common to the two treatment stations, intended to measure the flow of precursor gas (acetylene for example) injected into the two containers to be treated. The flow meter 37, mounted on an outer face of the detachable unit 7 and connected to a duct 38 for supplying precursor gas, emerges through a channel 39 on the face 8b of the detachable unit 7 and a channel 40, drilled in return in the cover 3 communicates with the two injectors (not shown) positioned in the upper portion above the jackets 4 and coaxial thereto.

It should be emphasized that the power (electric or pneumatic) supply to the detachable unit 7 can advantageously be made by means of automatic connections, in particular by means of a combined electric-pneumatic connection as illustrated by the connection 40 of the detachable unit 7 and the fixed connection 41 of the cover 3 in FIG. 5 (the connection 40 is not shown in FIG. 6).

The arrangements according to the invention can find an application in installations with various designs and in particular in a preferred manner, although not exclusively, in an installation which, for each treatment station 1, the cover 3 is fixed to and integral with the respective chamber 2 and the bottom of the chamber 2 can be displaced axially in order to allow for the introduction and removal of containers, positioned neck upwards, through the bottom of the chamber 2.

In addition, the arrangements according to the invention are all particularly suitable for a high performance installation with a high throughput, equipped with a large number of treatment stations, such as those of the revolving carousel type and comprising a rotating frame supporting said multiplicity of treatment stations 1 distributed around the perimeter, in which the detachable unit 7 are mounted respectively on the sides of the covers 3 of the treatment stations that are turned radially outwards. In this way easy direct access is available to the detachable units from outside the installation without it being necessary to invert or demount other components, which makes it possible to reduce, here also, the time of operations for exchanging the detachable units 7.

1. Installation for depositing, by means of a microwave plasma, a coating forming a barrier on the internal face of containers made of a thermoplastic, such as PET, this installation comprising a multiplicity of stations for the treatment of containers, each of which has a treatment chamber and a cover including a vacuum pumping chamber with which the functional components of said installation are in communication, liable to be covered, at least partially, with a powdery material constituting said coating during the operation of the installation,
wherein said functional components comprise solenoid valves for selectively controlling the establishment of a vacuum and atmospheric pressure inside the chamber and inside the container to be treated and are grouped together in a detachable unit that can be attached to said cover and are sheltered inside respective housings provided in a coupling face of said detachable unit; wherein said cover incorporates functional connections that are necessary for the respective functioning of said functional components and that open on a coupling face of said cover, said coupling faces of the detachable unit and of the cover being mutually matched in a complementary manner; and
wherein said connections and said housings sheltering the respective functional components are connected respectively when said detachable unit is mounted on said cover with their respective coupling faces mutually cooperating.

2. Installation according to claim 1, wherein:
the treatment stations are in even numbers,
each group of treatment stations comprises two adjacent stations, and
said functional components of said two adjacent stations of a group of stations are grouped together in said common detachable unit that can be attached to the coupling faces of the covers of two respective stations.

3. Installation for depositing, by means of a microwave plasma, a coating forming a barrier on the internal face of containers made of a thermoplastic, such as PET, this installation comprising a multiplicity of stations for the treatment of containers, each of which has a treatment chamber and a cover including a vacuum pumping chamber with which the functional components of said installation are in communication, liable to be covered, at least partially, with a powdery material constituting said coating during the operation of the installation,
wherein the treatment stations are in even numbers,
wherein each group of treatment stations comprises two adjacent stations;
wherein said functional components of said two adjacent stations of a group of stations are grouped together in a common detachable unit that can be attached to the coupling faces of the covers of the two respective stations and are sheltered in respective housings provided in a coupling face of said detachable unit;
wherein said cover incorporates functional connections that are necessary for the respective operation of said functional components and that open on a coupling face of said cover, said coupling face of the detachable unit and of the cover being mutually matched in a complementary manner; and
wherein said connections and said housings sheltering the respective functional components are connected respectively when said detachable unit is mounted on said cover with their respective coupling faces mutually cooperating.

4. Installation according to claim 3, wherein said functional components comprise solenoid valves for selectively controlling the establishment of a vacuum and atmospheric pressure inside the chamber and inside the container to be treated.

5. Installation according to claim 1, wherein said functional components comprise at least one vacuum sensor and/or at least one flow meter.

6. Installation according to claim 1, wherein the housings of the solenoid valves controlling the vacuum inside the container are positioned in portions of the detachable unit projecting on the coupling face, and wherein the coupling face of the cover has recesses, with complementary shapes, able to receive said projecting portions.

7. Installation according to claim 1, wherein said coupling face 8a of the detachable unit projects with respect to an assembling face supporting mechanical means of connection with the cover, and wherein the cover has a recess capable of receiving said projecting coupling face.

8. Installation according to claim 1, wherein the treatment stations are distributed in groups comprising several adjacent stations, wherein a common detachable unit groups together the functional components of said several adjacent stations of a group of stations, and wherein said detachable unit can be attached to the coupling faces of the covers of the respective stations.

9. Installation according to claim 8, wherein the chambers of adjacent treatment stations of a group of stations are brought together and juxtaposed, and wherein the respective covers are also juxtaposed.

10. Installation according to claim 8, wherein the chambers of adjacent treatment stations of a group of stations are brought together and juxtaposed, wherein the respective covers are also juxtaposed, wherein the treatment stations of a group of stations are provided with a common single cover, and wherein said detachable unit can be attached to the coupling face of the common cover.

11. Installation according to claim 1, in which the following are functionally associated with each work station:
a solenoid valve for controlling the establishment of a vacuum in the internal volume of the chamber outside the container to be treated,
a solenoid valve for controlling the establishment of a vacuum in the internal volume of the container to be treated,
a solenoid valve for controlling the re-establishment of atmospheric pressure inside the volume of the chamber outside the container to be treated, and
a solenoid valve for controlling the re-establishment of atmospheric pressure in the internal volume of the container to be treated,
wherein the treatment stations are distributed in groups comprising several adjacent stations,
wherein a common detachable unit groups together the functional components of said several adjacent stations of a group of stations,
wherein said detachable unit can be attached to the coupling faces of the covers of the respective stations, and
wherein:
it comprises a solenoid valve for controlling the establishment of a vacuum in the internal volume of the container to be treated and a solenoid valve for controlling the re-establishment of atmospheric pressure in the internal volume of the container to be treated for each treatment station; and
it comprises a single solenoid valve for controlling the establishment of a vacuum in the internal volume of the chamber outside the container to be treated and a single solenoid valve for controlling the re-establishment of atmospheric pressure in the internal volume of the chamber outside the container to be treated that are common to all the treatment stations of the group of treatment stations.

12. Installation according to claim 1, wherein, for each treatment station:
the cover is fixed to and integral with the respective chamber, and
the bottom of the chamber can be displaced axially in order to allow for the introduction and removal of containers, positioned with their necks uppermost, through the bottom of the chamber.

13. Installation according to claim 1, being of the revolving carousel type and comprising a revolving frame supporting said multiplicity of treatment stations distributed around the perimeter, and in which the detachable units are mounted respectively on the sides of the covers of the treatment stations that are turned radially outwards.
